(19) United States
(12) Patent Application Publication
(10) Pub. No.: US 2026/0005014 A1
(43) Pub. Date: Jan. 1, 2026

(54) METHOD FOR OXIDATION OF TOP SILICON LAYER IN BONDED WAFER

(71) Applicant: SHANGHAI SIMWINGS TECHNOLOGY CO., LTD, Shanghai (CN)

(72) Inventors: Ziwen WANG, Shanghai (CN); Wei ZHU, Shanghai (CN); Yuhao ZHOU, Shanghai (CN); Xing WEI, Shanghai (CN); Wei LI, Shanghai (CN)

(21) Appl. No.: 19/253,057

(22) Filed: Jun. 27, 2025

(30) Foreign Application Priority Data
Jun. 27, 2024 (CN) 202410855390.4

(51) Int. Cl. H01L 21/02; C23C 8/12; C23C 8/80; H01L 21/311

(52) U.S. Cl. CPC H01L 21/02238; C23C 8/12; C23C 8/80; H01L 21/31111

(57) ABSTRACT

The present invention provides a method for sacrificed oxidation of a top silicon layer in a bonded wafer, including: providing the bonded wafer, which includes a substrate layer, the top silicon layer and an insulating buried oxide layer; and performing first and second furnace oxidation processes on the top silicon layer. A first oxide layer is formed on the surface of the top silicon layer, and a second oxide layer is formed on the surface of the top silicon layer as a result of the second furnace oxidation process. The first and second oxide layers have complementary thickness profiles on a top surface of the top silicon layer, and the first and second furnace oxidation processes are followed by respective wet etching processes for removing the first and second oxide layers. With the present invention, the top silicon layer can be thinned, and its thickness uniformity can be improved.

### CROSS-REFERENCES TO RELATED APPLICATION

This application claims the priority of Chinese patent application number 202410855390.4, filed on Jun. 27, 2024 and entitled “METHOD FOR OXIDATION OF TOP SILICON LAYER IN BONDED WAFER”, the entire contents of which are incorporated herein by reference.

### TECHNICAL FIELD

The present invention relates to the field of semiconductor technology and, in particular, to a method for sacrificed oxidation of a top silicon layer in a bonded wafer.

### BACKGROUND

With the rapid development of integrated circuit technology, the size of wafers used in this industry has expanded from 6 inches to 8 inches, and further to 12 inches, in the pursuit of lower cost. However, thin films formed on larger wafers are imposed with more stringent requirements on their thickness uniformity. For example, for thin films formed on 6- and 8-inch wafers, a thickness variation (an indicator of uniformity of such thin films) on the order of a few tenths of a micron would be generally considered acceptable, but for those on 12-inch wafers, the thickness variation is required to be on the order of several nanometers. Such stricter thickness uniformity requirements on thin films formed on larger wafers are attributable to the evolution of process node. Forming a highly uniform thin film on a 12-inch wafer is challenging for the primary reason that there tends to be a film thickness difference between the center and periphery of the wafer, which occurs mainly due to a non-uniform temperature distribution across the wafer. This problem would seriously affect the fabrication of silicon-on-insulator (SOI) wafers. A top silicon layer in a SOI wafer can be thinned either using a contact-based technique (e.g., grinding or chemical polishing), or using a contactless thinning technique (e.g., furnace oxidation or wet etching). One currently available approach for thinning a top silicon layer in a SOI wafer contactlessly is to use a furnace oxidation process, which combines dry oxidation process with wet oxidation process to grow an oxide layer. In this process, since wet oxidation process proceeds faster (5-10 times faster than dry oxidation process), it is allowed to play an extremely dominant role (dry oxidation process lasts for such a short period of time that its contribution is almost ignorable), in order to achieve higher throughput. However, the resulting oxide layer tends to be non-uniform in thickness (it is usually thicker above the center than above the periphery, of the wafer). As a consequence, after subsequent film lifting based on wet etching (for removing the oxide layer), the top silicon layer may have unsatisfactory thickness uniformity, which may adversely affect the yield of integrated circuits fabricated on the wafer. Therefore, optimizing the furnace oxidation process is of great significance for the fabrication of a SOI wafer with a uniformly thick top silicon layer.

### SUMMARY

It is an object of the present invention to provide a method for sacrificed oxidation of a top silicon layer in a bonded wafer, which enables the top silicon layer to be thinned with increased thickness uniformity.

To this end, the present invention provides a method for sacrificed oxidation of a top silicon layer in a bonded wafer, which includes:
providing the bonded wafer, which includes a substrate layer, the top silicon layer and an insulating buried oxide layer; and
performing a first furnace oxidation process and a second furnace oxidation process on the top silicon layer, a first oxide layer is formed on a surface of the top silicon layer by the first furnace oxidation process and a second oxide layer is formed on the surface of the top silicon layer by the second furnace oxidation process, a thickness profile of the first oxide layer is complementary to a thickness profile of the second oxide layer on a top surface of the top silicon layer, the first furnace oxidation process and the second furnace oxidation process followed by respective wet etching processes for removing the first oxide layer and the second oxide layer.

Optionally, each of the first and second furnace oxidation processes may include dry oxidation process and wet oxidation process.

Optionally, a contribution of the dry oxidation process in the first furnace oxidation process to a thickness of the first oxide layer may be less than 2%.

Optionally, a contribution of the dry oxidation process in the second furnace oxidation process to a thickness of the second oxide layer may be 5% to 15%.

Optionally, in the second furnace oxidation process, the dry oxidation process may precede the wet oxidation process.

Optionally, the thickness profile of the first oxide layer may feature a thickness of the first oxide layer around a center thereof, which is greater than a thickness of the first oxide layer along a periphery of the first oxide layer, and wherein the thickness profile of the second oxide layer may feature a thickness of the second oxide layer around a center thereof, which is smaller than a thickness of the second oxide layer along a periphery of the second oxide layer.

Optionally, thickness uniformity of each of the first and second oxide layers may be denoted as ΔT and expressed as:

$$Δ T = ( {T}_{max} - {T}_{min} ) / ( {T}_{max} + {T}_{min} ) ,$$

wherein Tₘₐₓ is a maximum thickness of the first or second oxide layer, and Tₘᵢₙ is a minimum thickness of the first or second oxide layer, wherein the thickness uniformity of each of the first and second oxide layers is within 0.2%.

Optionally, the thickness of the first oxide layer may gradually decrease from its center to its periphery, and the thickness of the second oxide layer may gradually increase from its center to its periphery.

Optionally, each of the first and second oxide layers may have a thickness variation less than 10% of its thickness.

Optionally, each of the wet etching processes may use an etchant including hydrofluoric acid at a concentration of 1% to 25%.

The present invention provides a method for sacrificed oxidation of a top silicon layer in a bonded wafer, which includes the steps of: providing the bonded wafer, which includes a substrate layer, the top silicon layer and an insulating buried oxide layer; and performing first and second furnace oxidation processes on the top silicon layer. A first oxide layer is formed on the surface of the top silicon layer as a result of the first furnace oxidation process, and a second oxide layer is formed on the surface of the top silicon layer as a result of the second furnace oxidation process. The first and second oxide layers have complementary thickness profiles on a top surface of the top silicon layer, and the first and second furnace oxidation processes are followed by respective wet etching processes for removing the first and second oxide layers. According to the present invention, the top silicon layer can be thinned through forming the first and second oxide layers on the top silicon layer using the first and second furnace oxidation processes and then removing the first and second oxide layers using the wet etching processes that follow the first and second furnace oxidation processes.

### BRIEF DESCRIPTION OF THE DRAWINGS

FIG. 1 shows a flowchart of a method for sacrificed oxidation of a top silicon layer in a bonded wafer according to an embodiment of the present invention.

FIG. 2 shows a thickness profile of a first oxide layer (as measured at 49 points thereof) formed in an exemplary first furnace oxidation process in a method for sacrificed oxidation of a top silicon layer in a bonded wafer according to an embodiment of the present invention.

FIG. 3 shows a thickness profile of a second oxide layer (as measured at 49 points thereof) formed in an exemplary second furnace oxidation process in a method for sacrificed oxidation of a top silicon layer in a bonded wafer according to an embodiment of the present invention.

FIG. 4 shows a thickness profile of an oxide layer (as measured at 49 points thereof) formed in an exemplary pure dry oxidation process in a method for sacrificed oxidation of a top silicon layer in a bonded wafer according to an embodiment of the present invention.

FIG. 5 shows the dependence of cycle time and wafers per hour (WPH) on dry oxidation process contribution in a method for sacrificed oxidation of a top silicon layer in a bonded wafer according to an embodiment of the present invention.

### DETAILED DESCRIPTION

Objects, advantages and features of the present invention will become more apparent upon reading the following more detailed description with reference to the accompanying drawings, which illustrate particular embodiments thereof. Note that the figures are provided in a very simplified form not necessarily drawn to exact scale for the only purpose of helping to explain the disclosed embodiments in a more convenient and clearer way. In addition, the illustrated structures are usually part of their real-world counterparts. In particular, as the figures tend to have distinct emphases, they are sometimes drawn to different scales.

As used herein, the singular forms “a”, “an” and “the” include plural referents, and the term “or” is generally employed in the sense of “and/or”, “a number of” of “at least one”, and “at least two” of “two or more”. Additionally, the use of the terms “first”, “second” and “third” herein is intended for illustration only and is not to be construed as denoting or implying relative importance or as implicitly indicating the numerical number of the referenced items. Accordingly, defining an item with “first”, “second” or “third” is an explicit or implicit indication of the presence of one or at least two such items. The terms “one end” and “other end” may be used herein to generally refer to two complementary portions. Those of ordinary skill in the art can understand the specific meanings of the above-mentioned terms herein, depending on their context.

FIG. 1 shows a flowchart of a method for sacrificed oxidation of a top silicon layer in a bonded wafer according to embodiments of the present invention. As shown in FIG. 1, the method includes the steps of:
S1) providing the bonded wafer, which includes a substrate layer, the top silicon layer and an insulating buried oxide layer; and
S2) performing first and second furnace oxidation processes on the top silicon layer. A first oxide layer is formed on the surface of the top silicon layer as a result of the first furnace oxidation process, and a second oxide layer is formed on the surface of the top silicon layer as a result of the second furnace oxidation process. The first and second oxide layers have complementary thickness profiles on a top surface of the top silicon layer, and the first and second furnace oxidation processes are followed by respective wet etching processes for removing the first and second oxide layers.

The proposed method will be described in greater detail below.

In step S1, the bonded wafer is provided, which is a silicon-on-insulator (SOI) wafer and includes a substrate layer, the top silicon layer and an insulating buried oxide layer. The insulating buried oxide layer lies between the substrate layer and the top silicon layer. A process for forming the bonded wafer may include providing two silicon wafers respectively as a device wafer and a carrier wafer. Without limitation, each of the device and carrier wafers may have a thickness of 500 μm to 800 μm, such as 775 μm, and a thickness variation less than 0.5 μm, which is defined as the difference between maximum and minimum thicknesses. The device wafer may be cleaned and then oxidized so that a third oxide layer is formed on its surface. The third oxide layer may have a thickness of 2000 Å. An ion implantation process may be then performed from one side of the device wafer to form an ion-implanted layer within the device wafer. The ion-implanted layer serves mainly for separation and delamination. Dopant ions implanted in the ion implantation process may include hydrogen ions or other inert ions. Subsequently, the ion-implanted side of the device wafer may be bonded to the carrier wafer, and the bonded wafer may be obtained from a delamination process following the bonding process. Specifically, the side of the device wafer with the ion-implanted layer may be bonded to the carrier wafer, and separation may take place at the ion-implanted layer in the delamination process. As a result, the bonded wafer may be obtained as being made up of the carrier wafer, which provides the substrate layer, the portion of the device wafer retained on the substrate layer, which provides the top silicon layer, and the third oxide layer between the device and carrier wafers, which provides the insulating buried oxide layer. The bonded wafer may then undergo a strengthening process for enhancing adhesion of the substrate layer to the top silicon layer. The strengthening process may be a heat treatment process.

In step S2, first and second furnace oxidation processes are performed on the top silicon layer. A first oxide layer is formed on the surface of the top silicon layer as a result of the first furnace oxidation process, and a second oxide layer is formed on the surface of the top silicon layer as a result of the second furnace oxidation process. The first and second furnace oxidation processes are followed by respective wet etching processes for removing the first and second oxide layers. A uniform thickness of the top silicon layer can be obtained from the etching processes. Specifically, the first furnace oxidation process is performed to oxidize a portion of the top silicon layer into the first oxide layer, which is removed by the subsequent respective wet etching process, resulting in removal of a partial thickness of the top silicon layer. The second furnace oxidation process is performed to oxidize another portion of the top silicon layer into the second oxide layer, which is removed by the subsequent respective wet etching process, resulting in removal of another partial thickness of the top silicon layer. The present invention is not limited to any particular order in which the first and second furnace oxidation processes are carried out. That is, it is possible either the first furnace oxidation process precedes the second furnace oxidation process or that the second furnace oxidation process precedes the first furnace oxidation process, as long as each of these furnace oxidation processes is followed by a respective wet etching process for removing the oxide layer formed in the specific furnace oxidation process and the later furnace oxidation process follows the first wet etching process. For example, the first furnace oxidation process may be first carried out to oxidize a portion of the top silicon layer into the first oxide layer, and a wet etching process may then follow to remove the first oxide layer. Subsequently, the second furnace oxidation process may be carried out to oxidize another portion of the top silicon layer into the second oxide layer, and another wet etching process may then follow to remove the second oxide layer. In this way, a partial thickness of the top silicon layer is removed (i.e., contactless thinning of the top silicon layer is accomplished). Generally, the total thickness loss of the top silicon layer is 45% to 55% of the sum of the thicknesses of the two oxide layers formed in the respective furnace oxidation processes (i.e., the first and second oxide layers). In a preferred embodiment, hydrofluoric acid at a concentration of 1% to 25% may be used as an etchant in the wet etching processes, and the first and second oxide layers may be removed by exposing the entire wafer or one or more intended parts thereof to the etchant. Further, in the oxidation processes, the side surface of the top silicon layer will also be oxidized, forming an oxide layer thereon. However, in the context of the embodiments disclosed herein, the resulting material loss from the side surface of the top silicon layer is ignorable.

According to embodiments disclosed herein, the first and second oxide layers formed on the top surface of the top silicon layer (i.e., the surface thereof away from the substrate layer) have complementary thickness profiles. Specifically, the thickness profile of the first oxide layer formed on the top surface of the top silicon layer features a thickness of the first oxide layer around the center thereof, which is larger than a thickness along the periphery of the first oxide layer. On the contrary, the thickness profile of the second oxide layer formed on the top surface of the top silicon layer features a central thickness of the second oxide layer, which is less than a peripheral thickness thereof. The thickness of the first oxide layer on the top surface of the top silicon layer may gradually decrease from the center to the periphery of the first oxide layer, while the thickness of the second oxide layer on the top surface of the top silicon layer may gradually increase from the center to the periphery of the first oxide layer. The thickness profiles of the first and second oxide layers on the top surface of the top silicon layer are related to respective amounts of oxidation of the top silicon layer. A greater thickness of the first or second oxide layer means a larger amount of oxidation of the top silicon layer. On the contrary, a smaller thickness of the first or second oxide layer means a smaller amount of oxidation of the top silicon layer. Because of the complementary thickness profiles of the first and second oxide layers on the top surface of the top silicon layer, after undergoing the two furnace oxidation processes, different portions of the top silicon layer (including central and peripheral portions) have an approximately equal total amount of oxidation. This allows the top silicon layer to have a reduced thickness variation (defined as the difference of maximum and minimum thickness thereof), i.e., improved thickness uniformity, after the first and second oxide layers are removed by the wet etching processes. For example, after the first oxide layer is formed and then removed, the top silicon layer may be generally thinner around the center and thicker along the periphery (indicating a relatively large thickness variation). As a result, the subsequent formation of the second oxide layer may involve a larger amount of oxidation around the center and a smaller amount of oxidation along the periphery of the top silicon layer, so the resulting second oxide layer may have a smaller thickness around the center than along the periphery. Accordingly, after the second oxide layer is removed, the thickness variation of the top silicon layer will be reduced, resulting in a more uniform thickness of the top silicon layer.

According to embodiments disclosed herein, the thickness uniformity of each of the first and second oxide layers may be denoted as ΔT and expressed as:

$$Δ T = ( {T}_{max} - {T}_{min} ) / ( {T}_{max} + {T}_{min} ) ,$$

where Tₘₐₓ is the maximum thickness of the first or second oxide layer, and Tₘᵢₙ is the minimum thickness of the first or second oxide layer. Preferably, the thickness uniformity of each of the first and second oxide layers is within 0.2%.

According to embodiments disclosed herein, the thickness variation of each of the first and second oxide layers is preferably less than 10% of its thickness, and most preferably, the thickness of the first oxide layer is comparable to that of the second oxide layer. That is, the thickness variations of the first and second oxide layers are preferred to be as small as possible because this allows different portions of the top silicon layer that has undergone the two furnace oxidation processes (including central and peripheral portions) to have an approximately equal total amount of oxidation, i.e., the resulting top silicon layer has a reduced thickness variation and increased thickness uniformity. The thickness of the first oxide layer may be obtained as an average of all thickness measurements taken at different points of the first oxide layer. Likewise, the thickness of the second oxide layer may be obtained as an average of all thickness measurements taken at different points of the second oxide layer. According to embodiments disclosed herein, for both the first and second oxide layers, the thickness measurements are preferably taken at 49 points along the periphery and around the center.

According to embodiments disclosed herein, both the first and second furnace oxidation processes may involve dry oxidation process and wet oxidation process. The first furnace oxidation process may involve dry oxidation process and wet-dry oxidation process. Moreover, dry oxidation process may make a contribution of less than 2% to the thickness of the resulting first oxide layer, and wet oxidation process may proceed for a longer time at a higher oxidation rate. As a result, the first oxide layer formed in the first furnace oxidation process may be thicker around the center and thinner along the periphery. Preferably, in the second furnace oxidation process, dry oxidation process is followed by wet oxidation process and makes a contribution of 5% to 15%, preferably 10%, to the thickness of the resulting second oxide layer. Through controlling the contribution of the dry oxidation process to the thickness of the second oxide layer (i.e., the proportion of a thickness of the oxide layer grown during dry oxidation process in the total thickness of the oxide layer grown over the entire furnace oxidation process) in this way, the second oxide layer obtained from the second furnace oxidation process may be thinner around the center and thicker along the periphery. Despite a similar thickness profile of the resulting oxide layer, which is thinner around the center and thicker along the periphery, the use of a pure dry oxidation process would lead to undesired slow oxidation. Therefore, through controlling the contribution of dry oxidation process to the thickness of the resulting oxide layer can not only reduce the time required for oxidation, but can also create a desired thickness profile of the resulting oxide layer, which is thinner around the center and thicker along the periphery.

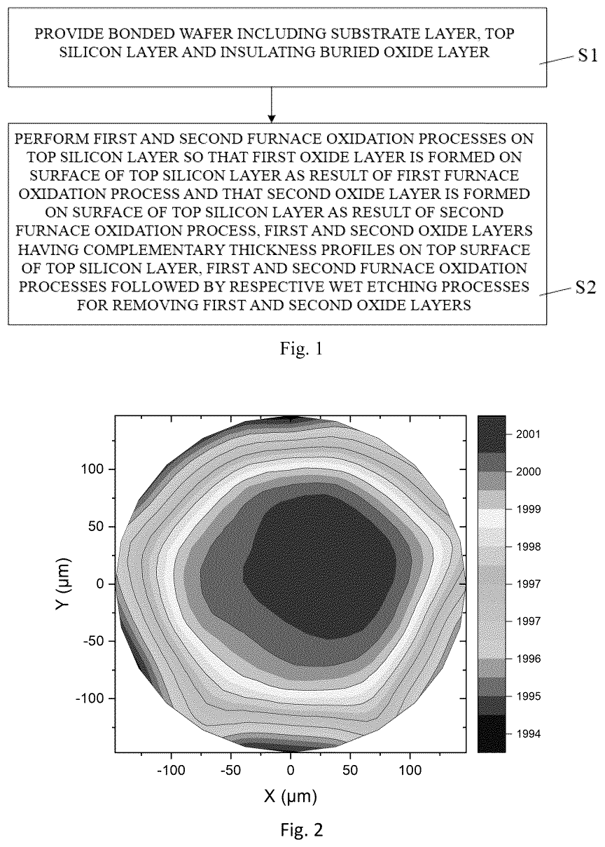

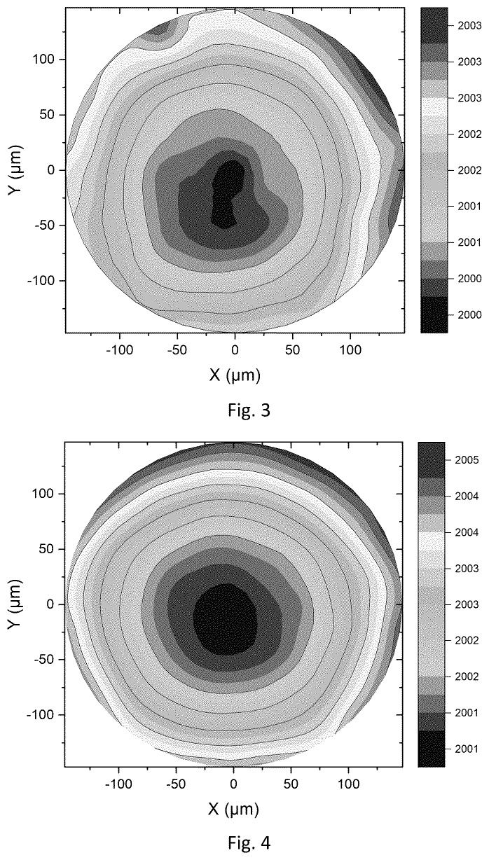

FIG. 2 shows a thickness profile of a first oxide layer (as measured at 49 points thereof) formed in an exemplary first furnace oxidation process in the method according to an embodiment of the present invention. FIG. 3 shows a thickness profile of a second oxide layer (as measured at 49 points thereof) formed in an exemplary second furnace oxidation process in the method according to an embodiment of the present invention. FIG. 4 shows a thickness profile of an oxide layer (as measured at 49 points thereof) formed in an exemplary pure dry oxidation process in the method according to an embodiment of the present invention. In FIGS. 2 to 4, the thickness profiles were each measured at 49 points.

TABLE 1
Parameters of Three Exemplary Furnace Oxidation Processes

| | | Contribution | | | | | |
|---|---|---|---|---|---|---|---|
| | | of Dry | | | | | |
| | Target | oxidation | Duration of | | Duration of | | |
| Furnace | Oxide | process to | Dry | | Wet | | Total |
| Oxidation | Layer | Oxide Layer | oxidation | | oxidation | Thickness | Duration of |
| Process | Thickness | Thickness | process | | process | Profile | Oxidation |
| 1 | 2000 Å | 1% | 5 | min | 45 min | thicker around | 50 min |
| | | | | | | the center and | |
| | | | | | | thinner along | |
| | | | | | | the periphery | |
| 2 | 2000 Å | 10% | 1 | h | 41 min | thinner | 1 h and 41 |

| | | | | | | |
|---|---|---|---|---|---|---|
| | | | | | around the | min |
| | | | | | center and | |
| | | | | | thicker along | |
| | | | | | the periphery | |
| 3 | 2000 Å | 100% | 15 h and 35 | 0 | thinner | 15 h and 35 |
| | | | min | | around the | min |
| | | | | | center and | |
| | | | | | thicker along | |
| | | | | | the periphery | |

Table 1 lists parameters of the three exemplary furnace oxidation processes. In Table 1, “Furnace Oxidation Process I” represents the exemplary first furnace oxidation process, “Furnace Oxidation Process II” represents the exemplary second furnace oxidation process, and the “Furnace Oxidation Process III” represents the exemplary pure dry oxidation process. The column “Contribution of Dry Oxidation to Oxide Layer Thickness” presents the concentrations of dry oxidation process in the respective processes to the thicknesses of the respective resulting oxide layers. Referring to FIG. 2, in conjunction with Table 1, in order to form the first oxide layer, the exemplary first furnace oxidation process specifically involved: introducing oxygen at a high temperature of 950° C. and 5 standard litres per minute (slm) (dry oxidation process); 5 min later, introducing and igniting hydrogen at 2 slm and reducing the flow rate of hydrogen to 4 slm (wet oxidation process); and ending the process 45 min later when the first oxide layer grew to 2000 Å. As can be seen from FIG. 2, the resulting first oxide layer was thicker around the center and thinner along the periphery. Accordingly, the top silicon layer experienced more material removal around the center than along the periphery in a subsequent wet etching process.

Referring to FIG. 3, in conjunction with Table 1, in order to form the second oxide layer, the exemplary first furnace oxidation process specifically involved: introducing oxygen at a high temperature of 950° C. and 5 slm (dry oxidation process); 1 h later when the oxide layer grew to a thickness of 200 Å, introducing and igniting hydrogen at 2 slm and reducing the flow rate of hydrogen to 4 slm (wet oxidation process); and ending the process 41 min later when the first oxide layer grew to 2000 Å. As can be seen from FIG. 3, the resulting second oxide layer was thinner around the center and thicker along the periphery. Accordingly, the top silicon layer experienced less material removal around the center than along the periphery in a subsequent wet etching process, complementary to what happened in the wet etching process that followed the exemplary first furnace oxidation process. These counteracted each other, resulting in a more uniform thickness of the top silicon layer.

Referring to FIG. 4, in conjunction with Table 1, in order to form the oxide layer, the exemplary pure dry oxidation process specifically involved: introducing oxygen at a high temperature of 950° C. and 5 slm (dry oxidation process); and ending the process 15 h and 35 min later when the oxide layer grew to 2000 Å. As can be seen from FIG. 4, the resulting oxide layer was thinner around the center and thicker along the periphery. Accordingly, the top silicon layer experienced less material removal around the center than along the periphery in a subsequent wet etching process, complementary to what happened in the wet etching process that followed the exemplary first furnace oxidation process. These counteracted each other, resulting in a more uniform thickness of the top silicon layer. However, this pure dry oxidation process took an excessively long time, leading to lower throughput. Therefore, controlling the contribution of dry oxidation process to the thickness of the resulting oxide layer can not only reduce the time required for oxidation, but can also create a desired thickness profile of the resulting oxide layer, which is thinner around the center and thicker along the periphery.

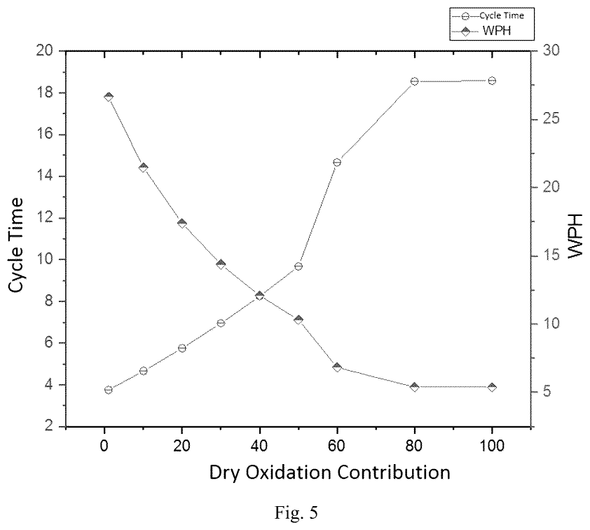

FIG. 5 shows the dependence of cycle time and wafers per hour (WPH) on dry oxidation process contribution in the method according to an embodiment of the present invention. In FIG. 5, the abscissa (“Dry oxidation process Contribution”) represents the contribution of dry oxidation process to the thickness of the oxide layer formed in the dry oxidation process (%), and the ordinates represent normalized relative cycle time and WPH. As can be seen from FIG. 5, a higher dry oxidation process contribution leads to a longer cycle time and a smaller WPH value. A combined consideration of cost, throughput and thickness profiling suggests that the most preferred contribution of dry oxidation process to the thickness of the resulting oxide layer be 5% to 15%.

Three comparative examples are set forth below to further explain the proposed method.

In a first comparative example, two silicon wafers were provided respectively as a device wafer and a carrier wafer. Each of the device and carrier wafers had a thickness of 775 μm and a thickness variation less than 0.5 μm. The device wafer was cleaned and then oxidized, and a third oxide layer having a thickness of 2000 Å was thereby formed on the surface thereof. An ion implantation process was performed on the device wafer to form an ion-implanted layer around the surface of the device wafer. In the ion implantation process, hydrogen ions were implanted as dopant ions with energy of 60 keV at a dose of 5.5×10¹⁶ atoms/cm². The device wafer was bonded at the ion-implanted side to the carrier wafer, and both were then subjected to a delamination process, obtaining a bonded wafer, in which the carrier wafer served as a substrate layer, a retained portion of the device wafer as a top silicon layer (with a thickness of 450 nm and a thickness variation of about 10 Å), and the third oxide layer between the device and carrier wafers as an insulating buried oxide layer. The first and second furnace oxidation processes were then carried out on the top silicon layer, with a target thickness for the top silicon layer being determined as 250 nm (i.e., it was to be thinned by 200 nm). A corresponding target total thickness of oxide layers to be formed in the processes was determined to be about 400 nm, 200 nm (2000 Å) in each process. The oxidation processes were performed as with Furnace Oxidation Processes I and II in the above examples, and the final top silicon layer had a thickness variation of about 10 Å.

In a second comparative example, two silicon wafers were provided respectively as a device wafer and a carrier wafer. Each of the device and carrier wafers had a thickness of 775 μm and a thickness variation less than 0.5 μm. The device wafer was cleaned and then oxidized, and a third oxide layer having a thickness of 2000 Å was thereby formed on the surface thereof. An ion implantation process was performed on the device wafer to form an ion-implanted layer around the surface of the device wafer. In the ion implantation process, hydrogen ions were implanted as dopant ions with energy of 60 keV at a dose of 5.5×10¹⁶ atoms/cm². The device wafer was bonded at the ion-implanted side to the carrier wafer, and both were then subjected to a delamination process, obtaining a bonded wafer, in which the carrier wafer served as a substrate layer, a retained portion of the device wafer as a top silicon layer (with a thickness of 450 nm and a thickness variation of about 10 Å), and the third oxide layer between the device and carrier wafers as an insulating buried oxide layer. The first and second furnace oxidation processes were then carried out on the top silicon layer, with a target thickness for the top silicon layer being determined as 250 nm (i.e., it was to be thinned by 200 nm). A corresponding target total thickness of oxide layers to be formed in the processes was determined to be about 400 nm, 200 nm (2000 Å) in each process. The oxidation processes were performed as with Furnace Oxidation Processes I and III in the above examples, and the final top silicon layer had a thickness variation of about 10 Å. Therefore, it can be seen that the use of the pure dry oxidation process can also improve thickness uniformity of the top silicon layer, but this is undesirable due to an excessively long cycle time of the process, which will lead to lower throughput.

In a third comparative example, two silicon wafers were provided respectively as a device wafer and a carrier wafer. Each of the device and carrier wafers had a thickness of 775 μm and a thickness variation less than 0.5 μm. The device wafer was cleaned and then oxidized, and a third oxide layer having a thickness of 2000 Å was thereby formed on the surface thereof. An ion implantation process was performed on the device wafer to form an ion-implanted layer around the surface of the device wafer. In the ion implantation process, hydrogen ions were implanted as dopant ions with energy of 60 keV at a dose of 5.5×10¹⁶ atoms/cm². The device wafer was bonded at the ion-implanted side to the carrier wafer, and both were then subjected to a delamination process, obtaining a bonded wafer, in which the carrier wafer served as a substrate layer, a retained portion of the device wafer as a top silicon layer (with a thickness of 450 nm and a thickness variation of about 10 Å), and the third oxide layer between the device and carrier wafers as an insulating buried oxide layer. The first furnace oxidation process was then carried out twice on the top silicon layer, with a target thickness for the top silicon layer being determined as 250 nm (i.e., it was to be thinned by 200 nm). A corresponding target total thickness of oxide layers to be formed in the processes was determined to be about 400 nm, 200 nm (2000 Å) in each process. Each oxidation process was performed as with Furnace Oxidation Process I in the above example, and the final top silicon layer had a thickness variation of about 30 Å, indicating that repeating Furnace Oxidation Process I twice will lead to lower thickness uniformity of the top silicon layer.

In summary, the present invention provides a method for sacrificed oxidation of a top silicon layer in a bonded wafer, which includes the steps of: providing the bonded wafer, which includes a substrate layer, the top silicon layer and an insulating buried oxide layer; and performing first and second furnace oxidation processes on the top silicon layer. A first oxide layer is formed on the surface of the top silicon layer as a result of the first furnace oxidation process, and a second oxide layer is formed on the surface of the top silicon layer as a result of the second furnace oxidation process. The first and second oxide layers have complementary thickness profiles on a top surface of the top silicon layer, and the first and second furnace oxidation processes are followed by respective wet etching processes for removing the first and second oxide layers. According to the present invention, the top silicon layer can be thinned through forming the first and second oxide layers on the top silicon layer using the first and second furnace oxidation processes and then removing the first and second oxide layers using the wet etching processes that follow the first and second furnace oxidation processes. Moreover, since the first and second oxide layers formed on the top surface of the top silicon layer have complementary thickness profiles, the top silicon layer has a uniform thickness after it undergoes the wet etching process. Thus, thickness uniformity of the top silicon layer can be improved.

Presented above are merely a few preferred embodiments of the present invention, which do not limit the invention in any way. Changes in any forms made to the principles and teachings disclosed herein, including equivalents and modifications, by any person of ordinary skill in the art without departing from the scope of the invention are intended to fall within the scope of the invention.

1. A method for sacrificed oxidation of a top silicon layer in a bonded wafer, comprising:
providing the bonded wafer, which comprises a substrate layer, the top silicon layer and an insulating buried oxide layer; and
performing a first furnace oxidation process and a second furnace oxidation process on the top silicon layer, a first oxide layer is formed on a surface of the top silicon layer by the first furnace oxidation process and a second oxide layer is formed on the surface of the top silicon layer by the second furnace oxidation process, a thickness profile of the first oxide layer is complementary to a thickness profile of the second oxide layer on a top surface of the top silicon layer, the first furnace oxidation process and the second furnace oxidation process followed by respective wet etching processes for removing the first oxide layer and the second oxide layer.

2. The method of claim 1, wherein each of the first furnace oxidation process and the second furnace oxidation process comprises a dry oxidation process and a wet oxidation process.

3. The method of claim 2, wherein a contribution of the dry oxidation process in the first furnace oxidation process to a thickness of the first oxide layer is less than 2%.

4. The method of claim 2, wherein a contribution of the dry oxidation process in the second furnace oxidation process to a thickness of the second oxide layer is 5% to 15%.

5. The method of claim 4, wherein in the second furnace oxidation process, the dry oxidation process precedes the wet oxidation process.

6. The method of claim 1, wherein the thickness profile of the first oxide layer features a thickness of the first oxide layer around a center thereof, which is greater than a thickness of the first oxide layer along a periphery of the first oxide layer, and wherein the thickness profile of the second oxide layer features a thickness of the second oxide layer around a center thereof, which is smaller than a thickness of the second oxide layer along a periphery of the second oxide layer.

7. The method of claim 6, wherein thickness uniformity of each of the first oxide layer and the second oxide layer is denoted as ΔT and expressed as:
$$Δ T = ( {T}_{max} - {T}_{min} ) / ( {T}_{max} + {T}_{min} ) ,$$
wherein Tₘₐₓ is a maximum thickness of the first oxide layer or the second oxide layer, and Tₘᵢₙ is a minimum thickness of the first oxide layer or the second oxide layer, and wherein the thickness uniformity of each of the first oxide layer and the second oxide layer is within 0.2%.

8. The method of claim 6, wherein the thickness of the first oxide layer gradually decreases from the center to the periphery of the first oxide layer, and wherein the thickness of the second oxide layer gradually increases from the center to the periphery of the second oxide layer.

9. The method of claim 1, wherein each of the first oxide layer and the second oxide layer has a thickness variation less than 10% of a thickness of the first oxide layer or the second oxide layer.

10. The method of claim 1, wherein each of the wet etching processes uses an etchant comprising hydrofluoric acid at a concentration of 1% to 25%.
